(19) United States
(12) Patent Application Publication
(10) Pub. No.: US 2014/0061918 A1
(43) Pub. Date: Mar. 6, 2014

(54) METHOD OF FORMING LOW RESISTIVITY TaNx/Ta DIFFUSION BARRIERS FOR BACKEND INTERCONNECTS

(71) Applicants: Christopher Jezewski, Hillsboro, OR (US); Boyan Boyanov, Portland, OR (US); James J. Clarke, Portland, OR (US); Jacob M. Faber, Hillsboro, OR (US)

(72) Inventors: Christopher Jezewski, Hillsboro, OR (US); Boyan Boyanov, Portland, OR (US); James J. Clarke, Portland, OR (US); Jacob M. Faber, Hillsboro, OR (US)

(21) Appl. No.: 13/995,170

(22) PCT Filed: Dec. 27, 2011
(86) PCT No.: PCT/US11/67342

§ 371 Date: Jun. 17, 2013

(51) Int. Cl. H01L 21/768; H01L 23/532

(52) U.S. Cl. CPC H01L 21/76846; H01L 21/76879; H01L 23/53266; H01L 23/53261
USPC 257/751; 438/643

(57) ABSTRACT

The present disclosure relates diffusion barrier layers for backend layers for interconnects and their methods of manufacturing. A TaNₓ/Ta diffusion barrier layer used for backend interconnect is formed at a temperature between about 150-450° C. wherein the Ta film exhibits a body-centered-cubic (BCC) structure and a lower electrical resistivity. Other embodiments are described and claimed.

### BACKGROUND

The subject matter of the present disclosure relates generally to semiconductor processing, integrated circuits, diffusion barrier layers for backend interconnects, deposition of TaNₓ/Ta layer, and formation of alpha phase Ta for semiconductor device applications.

The push for ever-smaller and faster integrated circuits (IC) places enormous performance demands on the materials used to construct IC devices. In general, an IC chip is also known as a microchip, a silicon chip, or a chip. Integrated circuits chips are found in a variety of common devices, such as the microprocessors in computers, cars, televisions, CD players, and cellular phones. A plurality of IC chips are typically built on a silicon wafer and after processing the wafer is diced apart to create individual chips. A 1 cm² IC chip having feature sizes of about 90 nm can comprise hundreds of millions of components. Current technologies are pushing feature sizes even smaller than 45 nm. Due to a lower electrical resistivity, copper (Cu, resistivity=1.7 μΩ-cm) or Cu alloy has gradually replaced aluminum (Al, resistivity=2.8 μΩ-cm.) for backend interconnects between the electronic devices (e.g., transistors) in an IC chip. Other favorable features of Cu over Al include lower cost and better resistance to electromigration. Devices is an IC chip can be placed not only across the surface of the substrate but can also be stacked in a plurality of layers in the IC chip. Electrical interconnections between devices in different layers are established using vias and trenches that are filled with conducting materials. Layer(s) of insulating or dielectric materials, including low-k dielectric materials, separate the various components and devices in an IC chip.

Vias or trenches are structures having any shape formed in the dielectric layers. They may be patterned and etched using conventional wet or dry etch semiconductor processing techniques. Diffusion barrier layers are used between the metal interconnects and the dielectric materials to prevent metal (such as copper) migration into the surrounding materials. Device failure can occur in situations where copper metal migrates into the transistor structure, such as the source/drain, gate, gate dielectric, or channel region. Delamination due to poor adherence between materials is also a difficulty encountered in the fabrication of IC chips that leads to device failure. Diffusion barrier layers placed between a dielectric material and copper sometimes can also promote adhesion of the copper to the dielectric material and serves as adhesion layers.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a schematic diagram showing a backend interconnect structure in an IC chip in accordance with one or more embodiments.

FIGS. 2(a)-(d) are schematic diagrams showing processing steps to fabricate a backend interconnect in accordance with one or more embodiments.

FIG. 3 is a schematic diagram showing processes to fabricate a backend interconnect in accordance with one or more embodiments.

FIG. 4 is a schematic diagram showing a computing device in accordance with one or more embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present disclosure. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

A Cu interconnect typically uses single or dual damascene process, which etches a series of openings called trenches and vias in the insulating layer between different metal layers. Trenches are depressions or grooves, typically extending parallel to the top surface of the Si chip, that are patterned to connect circuits on the same level of the backend of the process. Vias are holes, typically extending perpendicular to the surface, that are patterned to connect the metal hues from different metal layers. Trenches and vias can be formed using standard photolithography and etch processes commonly known to a person having ordinary skill in the semiconductor field. Subsequently, they are filled with a diffusion barrier layer and a conducting material such as Cu. After Cu fill, chemical mechanical polishing process is used to remove the overfill material above the openings. Refractory metals and their nitrides, such as tantalum (Ta), tantalum nitride (TaN), titanium (Ti), and titanium nitride (TiN), are well known as diffusion barriers due to their chemical and thermal stability. For example, Ta film deposited on a TaN template has been widely used as a barrier layer for Cu metallization. Tantalum exists in two crystalline phases: alpha and beta. The alpha phase has a body-centered cubic (BCC) structure (space group Im3m, lattice constant a=0.33058 nm) and a relatively lower electrical resistivity of 15-60 μΩ-cm. The beta phase has a tetragonal crystal structure (space group P42/mnm, a=1.0194 nm, c=0.5313 nm) and a relatively higher electrical resistivity of 170-210 μΩ-cm. The beta phase is metastable and readily converts to the alpha phase upon heating to a temperature above 500-700° C. Although bulk Ta is almost entirely alpha phase, Ta thin film (<30 nm) used for diffusion barrier usually exists in a beta phase and therefore, has >100× higher electrical resistivity than Cu. Even, when the thin Ta film is annealed at a temperature above 500-700° C., the beta phase will not convert to the alpha phase. Due to a relatively higher resistivity compared with Cu, there is a consistent trend to reduce the thickness of the diffusion barrier layer. However, a minimum thickness of 3-5 nm is probably required in order to provide effective barrier to Cu diffusion. As a result, the ratio of barrier layer/Cu starts to increase as the via/trench size continues to shrink and the high electrical resistivity of the barrier layer becomes a significant obstacle to reduce interconnect resistance.

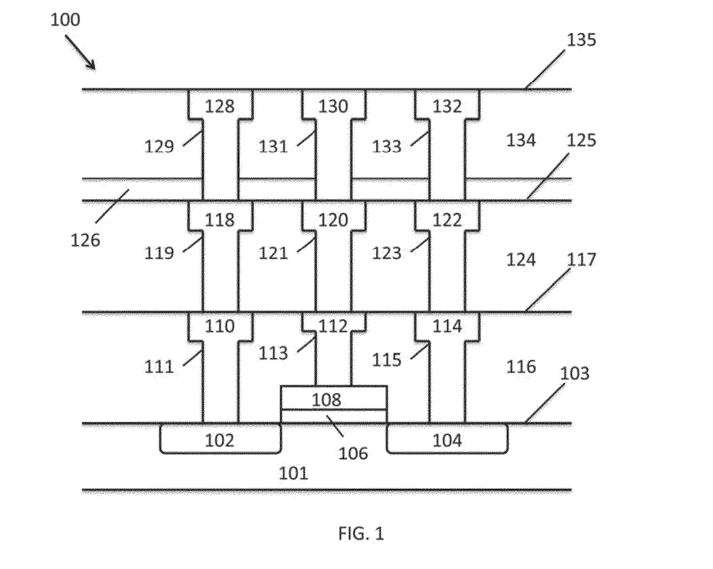

FIG. 1 is a schematic diagram showing a backend interconnect structure 100 in an IC chip in accordance with one or more embodiments. Substrate 101 may be a bulk semiconductor wafer, such as silicon, germanium, silicon-germanium, gallium arsenide, or other III-V semiconductor material, or it may have a semiconductor-on-insulator configuration such as silicon-on-insulator, germanium-on-insulator, silicon-germanium-on-insulator, or indium phosphide-on-insulator. Substrate 101 is shown with a field effect transistor having source 102 and drain 104 in the substrate and gate 108 and gate dielectric 106 above top surface 103. Dielectric layers 116, 124, and 134 are used to separate different metal levels (3 in this embodiment) and may comprise one or more of the conventional dielectric materials commonly used in the IC applications, such as oxides, doped oxides, nitrides, organic polymers, fluorosilicate glasses, and organosilicates. The dielectric material may also be a low-k dielectric material with pores or other voids to further reduce the dielectric constant, although the scope of the claimed subject matter is not limited in this respect. In one embodiment, each of the dielectric layers 116, 124, and 134 may comprise one or more layers of materials. The thickness of dielectric layers 116, 124, and 134 varies and in some example embodiments may be in the range of 50-5,000 nm. Via and trench openings 111, 113, and 115 in the dielectric layer 116 are filled with conducting material 110, 112, and 114, typically tungsten (W). Top surface 117 is planarized using chemical mechanical polishing. Via and trench openings 119, 121, and 123 in the dielectric layer 124 are filled with conducting materials 118, 120, and 122, such as Cu, Cu alloys, other conducting metals or conductors. A diffusion barrier layer (not shown) may be formed on the bottoms and/or sidewalls of via and trench openings 119, 121, and 123 prior to the filing with conducting materials 118, 120, and 122. Top surface 125 is planarized using chemical mechanical polishing. In case Cu or Cu alloy is used as interconnect metal, etch stop/cap layer 126, such as silicon nitride, is deposited over top surface 125. Trench and via openings 129, 131, and 133 in dielectric layer 134 are filled with conducting materials 128, 130, and 132, such as Cu, Cu alloys, other conducting metals or conductors. A diffusion barrier layer (not shown) may be formed on the bottoms and/or sidewalls of the via and trench openings 129, 131, and 133 prior to the filing with conducting materials 128, 130, and 132, Top surface 135 is planarized before another metal layer is built above it. Backend interconnect structure 100 can be used to connect circuits, components, and transistors at the same or different metal levels.

Although Cu has very favorable electrical properties for backend interconnect applications, it also has several drawbacks: (1) Copper is prone to oxidation and corrosion when it comes in contact with some commonly-used processing chemicals. (2) Copper is very mobile and tends to migrate to other regions of the device during subsequent processes of the Si chip. (3) Copper has weak bonding with many dielectric materials which causes delamination and reliability issues. In order to overcome these problems, a diffusion barrier layer and an adhesion layer (or liner) are usually deposited on the bottom and/or sidewalls of the trench and via before Cu fill. A diffusion barrier layer may comprise one or more layers of materials which may also provide adequate adhesion with Cu and serves as an adhesion layer. One such example is TaNₓ/Ta layer which is widely used in Cu interconnect as diffusion barrier.

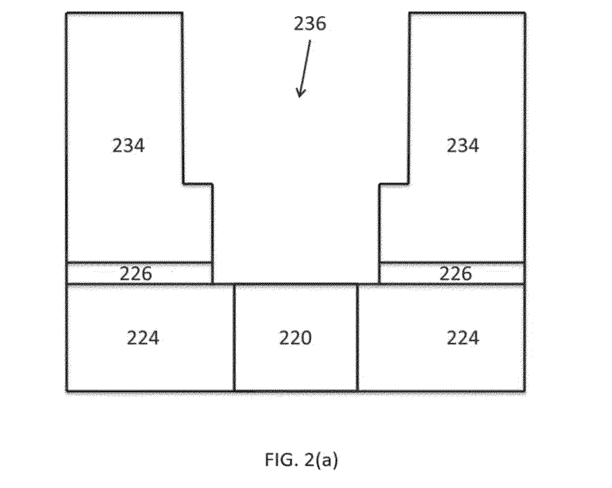

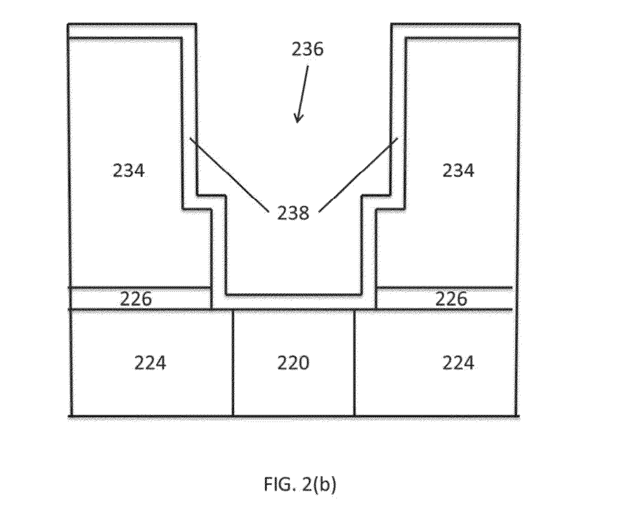

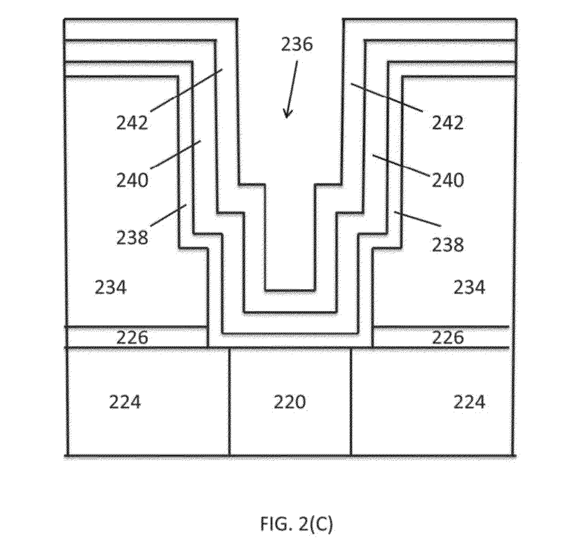

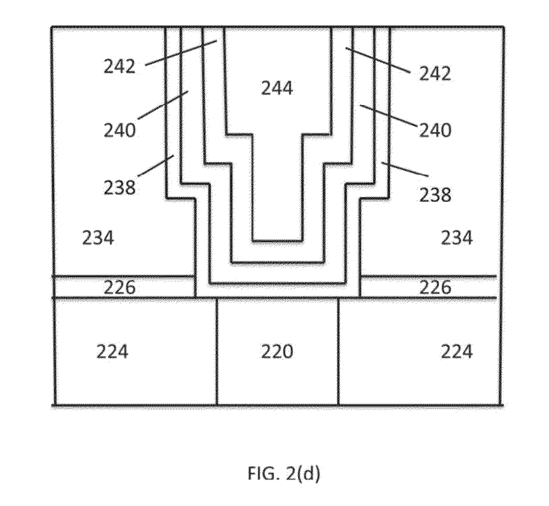

FIGS. 2(a)-(e) are schematic diagrams showing processing steps to fabricate a backend interconnect in accordance with one or more embodiments. FIG. 2(a) provides via/trench opening 236 in interlayer dielectric (ILD) 234, which may be formed by photolithography and etch techniques known to one of ordinary skill in the art of microelectronic device manufacturing. In one embodiment via/trench opening 236 may have rounded corners. In another embodiment, via/trench opening 236 may have asymmetrical sidewalls. In yet another embodiment, portion of the bottom of via/trench opening 236 may extend into ILD 224. In general, the via/trench opening 236 has a width in the approximate range of 0.005 microns (“μm”) to 5 μm, and the depth in the approximate range of 0.005 μm to 10 μm. Etch stop layer 226 exists between ILD 234 and ILD 224, which may be formed from a dielectric material, such as silicon nitride, silicon oxynitride, silicon carbide, or other dielectric material. ILD 234 and 224 may comprise one or more of the conventional dielectric materials commonly used in IC applications, such as oxides (e.g., silicon oxide, carbon doped oxide), nitrides, organic polymers (e.g., perfluorocyclobutane or polytetrafluoroethylene), spin-on low-k dielectrics, fluorosilicate glasses, and organosilicates (e.g., silsesquioxane, siloxane, or organosilicate glass). The ILD material may also be a low-k dielectric material with pores or voids to further reduce the dielectric constant, although the scope of the claimed subject matter is not limited in this respect. In one embodiment, ILD 234 and 224 may comprise one or more layers of materials. ILD 234 and 224 may be deposited using any suitable deposition technique such as chemical vapor deposition (CVD), sputtering, and spin-on deposition. Thickness of the ILD 234 and ILD 224 may be in the range of 50 nm-5 μm.

FIG. 2(b) provides deposition of diffusion barrier layer 238 on the sidewalls and bottom of via/trench opening 236. Diffusion barrier layer 238 may comprise a conducting material, such as Ta, Ti, Ru, Co, Pt, Ir, Pd, Re, Rh or combinations thereof. It may also comprise a nitride or an oxy-nitride of each of the above element, or combinations thereof. Any suitable technique, such as atomic layer deposition (ALD), CVD, sputtering, physical vapor deposition (PVD), electroplating, and electroless plating may be used to deposit diffusion barrier layer 238, usually with a thickness in the range of 1-100 nm. Diffusion barrier layer 238 may also serve as an adhesion layer and may comprise one or more layers of different materials to achieve the intended purposes. Although FIG. 2(b) shows a continuous, uniform diffusion barrier layer 236 that covers the entire surface of via/trench opening 236, in some cases, it may be discontinuous and/or may not cover every surface of via/trench opening 236. In one embodiment, diffusion barrier layer 236 has a non-uniform thickness.

In one embodiment according to current description, diffusion barrier layer 238 is a TaNₓ/Ta layer. A TaNₓ film, where x is in the approximate range of about 0.05-2.0 and preferably in the range of 0.05-0.35, is first deposited onto at least one surface of via/trench opening 236 by any suitable technique such as sputtering, CVD, ALD, plating, and electroless deposition at room temperature. The thickness of the TaNₓ film is in the range of about 0.5-5.0 nm. A Ta film in the thickness range of about 0.5-30 nm is subsequently deposited onto the TaNₓ film at room temperature. Based on X-ray diffractometry (XRD) pattern (not shown), the Ta film exhibits a beta phase Ta which has a tetragonal crystal structure and a typical electrical resistivity of 170-210 μΩ-cm.

In another embodiment according to current description, the diffusion barrier layer 238 is a TaNₓ/Ta layer. A TaNₓ film, where x is in the approximate range of about 0.05-2.0 and preferably in the range of 0.05-0.35, is first deposited onto at least one surface of via/trench opening 236 by any suitable technique at a temperature between about 150-450° C. The thickness of the TaNₓ film is in the range of about 0.5-5.0 nm. A Ta film in the thickness range of about 0.5-30 nm and preferably in the range of about 1-20 nm is subsequently deposited onto the TaNₓ film by sputter deposition (sputtering) at a temperature between about 150-450° C. with a re-sputter rate between about 1.0-10 and preferably between 1.0-1.35.

Sputter deposition is a process whereby atoms are ejected from a solid target by energetic particles, usually plasma, and re-deposited onto a substrate to form a thin film. It is commonly used in the semiconductor industry to form a metal layer such as Ta. Argon (Ar) plasma is usually used to dislodge Ta atoms from a solid Ta target, which are then deposited onto a substrate. The substrate can be heated to a higher temperature or maintained at room temperature during deposition. Re-sputter is a process that involves re-emission of the deposited material due to bombardment of energetic particles. Re-sputter rate is defined as the thickness of the barrier layer deposited without an AC bias divided by the thickness of the barrier layer deposited with an AC bias. The AC bias is normally between 0.01-100 GHz and preferably at approximately 13.56 MHz. A thin film deposited with an AC bias has a better conformality and step coverage than one without an AC bias. Based on X-ray diffractometry (XRD) pattern (not shown), the deposited Ta film exhibits an alpha phase Ta which has a body-centered cubic (BCC) structure and an electrical resistivity of 15-60 μΩ-cm. This is significantly lower than the electrical resistivity of a typical beta phase Ta film. Other deposition techniques that are known to the semiconductor industry can also be used to produce an alpha phase BCC Ta film. For example, Ta films can be deposited at about 150-450° C. on a TaNₓ layer using hallow cathode magnetron (HCM) or electron cyclotron resonance (ECR) deposition technique. The HCM design includes a hollow cathode structure surrounding a planar magnetron cathode while the ECR technique uses ECR to generate plasma. Both techniques can produce high energy plasma and high particle flux and, therefore, a high metal ionization during deposition. A Ta film prepared by either technique at about 150-450° C. exhibits the alpha phase. It shall be noted that ILD layer 234, 224, and etch stop layer 224 does not affect the formation of the alpha phase Ta and any suitable material and structure can be used for the ILD layers and the etch stop layer.

In yet another embodiment according to current description, the diffusion barrier layer 238 is a TaNₓ/Ta layer. A TaNₓ film, where x is in the approximate range of about 0.05-2.0 and preferably in the range of0.05-0.35, is first deposited onto at least one surface of via/trench opening 236 by reactive sputtering at a temperature between about 150-450° C.

Reactive sputtering occurs when the deposited film is formed through a chemical reaction between the target material and a gas (N₂, in this case) which is introduced to the process chamber during deposition. After a desired film thickness between about 0.5-5.0 nm is achieved, the plasma is turned off and N₂ gas is pumped out of the process chamber. Without breaking the vacuum, a Ta film in the thickness range of about 0.5-30 nm and preferably in the range of about 1-20 nm is subsequently deposited onto the TaNₓ film by sputtering in the same process chamber. The Ta film is deposited at a temperature between about 150-450° C. with a re-sputter rate between about 1.0-10 and preferably between 1.0-1.35. Based on XRD, the Ta film exhibits an alpha phase, BCC structure with a low resistivity of 15-60 μΩ-cm. The ILD layer 234, 224, and etch stop layer 224 does not affect the formation of the alpha phase Ta and any suitable material and structure may be used for the ILD layers and the etch stop layer.

FIG. 2(c) shows a subsequent formation of one or more conducting layers, Cu alloy layer 240 and Cu seed layer 242 in this embodiment, on top of diffusion barrier layer 238. Copper alloy layer 240 and Cu seed layer 242 can be formed using any suitable thin film technique known to one of ordinary skill in the art of semiconductor manufacturing, e.g., sputtering, ALD, CVD, electroplating, electroless plating, and the like. The thickness of Cu alloy layer 240 and Cu seed layer 242 is in the range of 1.0-100 nm. Cu alloy layer 240 and Cu seed layer 242 may comprise one or more dopants and may be continuous or discontinuous. The discontinuous Cu seed layer allows a thinner seed layer to be deposited and potentially avoids pinching off features in situations in which small features are to be filled with a metal. If a feature becomes pinched off, then an unwanted gap in the metal of the interconnect can form, which may lead to device failure. Cu alloy layer 240 and Cu seed layer 242 may have an uniform or non-uniform thickness. In one embodiment, other materials besides Cu may be used for layers 240 and 242, such as ruthenium (Ru), nickel (Ni), cobalt (Co), chromium (Cr), iron (Fe), manganese (Mn), titanium (Ti), aluminum (Al), hafnium (Hf), tantalum (Ta), tungsten (W). Vanadium (V), Molybdenum (Mo), palladium (Pd), gold (Au), silver (Ag), platinum (Pt), or combinations thereof. FIG. 2(d) shows filling of via/trench opening 236 with conducting material 244, Cu in this embodiment, and subsequent planarization of Cu layer 244. Electroplating is typically used to deposit Cu and fill via/trench opening 236. An electroplating process comprises the deposition of a metal onto a semiconductor substrate from an electrolytic solution that comprises ions of the metal to be deposited. The electrolyte solution can be referred to as a plating bath or an electroplating bath. The substrate to be plated is immersed in the plating bath with a negative bias placed on the substrate. The positive ions of the metal are attracted to the negatively biased substrate, which are reduced to form a metal layer on the substrate. Copper layer 244 may also comprise one or more dopants. In one embodiment, other material besides Cu may be used for conducting material 244, such as ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Ag), platinum (Pt), or combinations thereof. Any other suitable thin film technique known to a person having ordinary skill in the field may be used to deposit conducting material 244. Such technique includes sputtering, CVD, electroless plating, and the like. Finally, chemical mechanical polishing is used to remove portions of conducting material 244, conducting layers 242 and 240, and diffusion barrier layer 238 from the top surface of ILD 234 to planarize the top surface for subsequent processing.

Although FIG. 2 shows an interconnect structure within one metal level, more than one level of interconnect structures may be fabricated in an IC chip to connect circuits, components, or transistors. To fabricate more than one level of interconnect, similar process and structure as described in FIG. 2(a)-(d) may be repeated. The via/trench opening in each metal level may have the same or different width and depth. In one embodiment, the alpha phase Ta may be used as diffusion barrier for all metal levels. In another embodiment, one or more metal levels comprise alpha phase Ta and one or more metal levels comprise beta phase Ta. For example, in an embodiment where the size of the via/trench at lower metal levels is smaller than that at higher metal levels, one or more of the tower metal levels may have alpha phase Ta and one or more larger upper metal levels may have beta phase Ta at higher metal levels, although the scope of the claimed subject matter is not limited in this respect.

Kelvin tests were used to compare electrical resistance of via chains comprising TaNₓ/Ta barrier layer deposited at either room temperature or a higher temperature. The results show at least 26% reduction in electrical resistance when TaNₓ/Ta barrier layer is deposited at a temperature between 150-450° C., indicating the formation of a lower-resistivity BCC Ta phase. With a continued focus on smaller device size and faster device speed, reduction in electrical resistance of diffusion barriers is extremely important. When the critical dimension (CD) of the geometrical features in the semiconductor processes reaches 100 nm or less and the depth of the via is less than 100 nm, use of low-resistivity alpha Ta for barrier layer may be particularly helpful. For an embodiment with a total thickness of the Ta and/or TaNₓ of about 10 nm and a width of teach of about 100 nm, the alpha phase Ta and/or TaNₓ would take up roughly 20% (as there is Ta on both sides of the trench) of the side-to-side distance of the trench. As features get smaller, the alpha phase Ta and/or TaNₓ take up more and more of the via, such as 25%, 30% or even more. A via with a horizontal cross section having a layer or layers comprising Ta in alpha phase and taking up at least 20% of the via is thus within the scope of some embodiments.

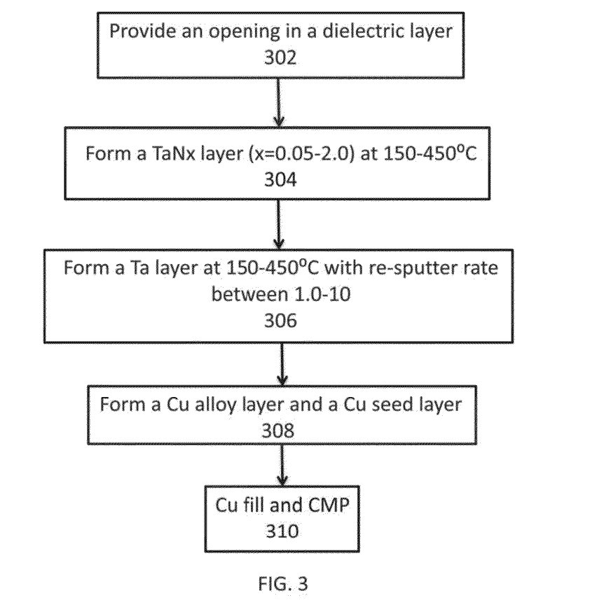

FIG. 3 describes a process for forming a Cu backend interconnect in accordance with one or more embodiments. In step 302, an opening is formed in a dielectric layer. A TaNₓ layer (x=0.05-2.0) is formed at 150-450° C. in step 304 on at least one surface of the bottom and sidewalls of the opening. Subsequently in step 306, a Ta layer is formed on top of the TaNₓ layer at 150-450° C. with a re-sputter rate between 1.0-10. The Ta film exhibits an alpha BCC phase with a lower electrical resistivity. A Cu alloy layer and a Cu seed layer are then formed on top of the Ta layer in step 408. Finally in step 310, Cu is deposited to fill the opening and the top surface is planarized by chemical mechanical polishing.

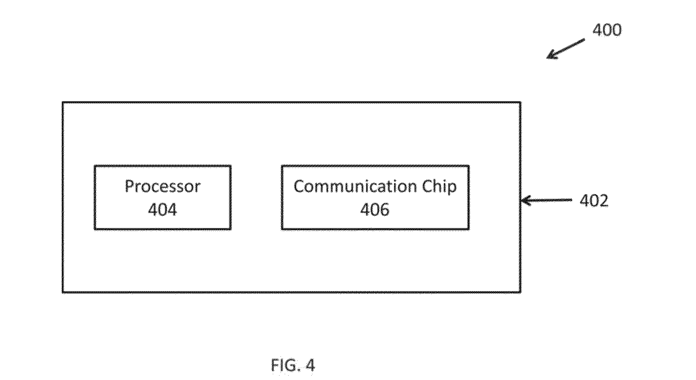

FIG. 4 illustrates a computing device 400 in accordance with one or more embodiments of the current disclosure. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a data entry device, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO. and others.

The processor 404 of the computing device 400 includes an integrated circuit die packaged within the processor 404. In some implementations of the invention, the integrated circuit die of the processor includes backend interconnects that comprise a TaNₓ/Ta diffusion barrier layer fabricated according to the structures and processes as described herein. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip includes backend interconnects that comprise a TaNₓ/Ta diffusion barrier layer fabricated according to the structures and processes as described herein.

In further implementations, another component housed within the computing device 400 may contain an integrated circuit die that includes backend interconnects comprising a TaNₓ/Ta diffusion barrier layer fabricated according to the structures and processes as described herein. In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 460 may be any other electronic device that processes data.

The above description of illustrated implementations of the claimed subject matter, including what is described in the Abstract, is not intended to be exhaustive or to limit the claimed subject matter to the precise forms disclosed. While specific implementations of, and examples for, the claimed subject matter are described herein for illustrative purposes, various equivalent modifications are possible within the scope of the disclosure, as those skilled in the relevant art will recognize. It should also be understood that the subject matter defined by the appended claims is not to be limited by particular details set forth in the above description, as many apparent variations thereof are possible without departing from the spirit or scope thereof. Reference throughout this specification to “one embodiment” or “an embodiment” means that a particular feature, structure, material, or characteristic described in connection with the embodiment is included in at least one embodiment of the subject matter, but does not necessarily denote that they are present in every embodiment. Furthermore, the particular features, structures, materials, or characteristics may be combined in any suitable manner in one or more embodiments. Various additional layers and or structures may be included and or described features may be omitted in other embodiments.

What is claimed is:

1. A method to fabricate a backend interconnect comprising:
forming an opening in a dielectric layer on a substrate, the opening having at least one surface;
forming a TaNₓ layer on the at least one surface of the opening, wherein x is approximately between about 0.05-2.0;
forming a Ta layer on the TaNₓ layer; wherein the Ta layer exhibits a body-centered cubic (BCC) structure;
forming one or more conducting layers on the Ta layer; and
depositing a conducting material in the opening.

2. The method of claim 1, wherein the Ta layer is formed by sputtering with a re-sputter rate between about 1.0-10 at about 150-450° C. and has a thickness between about 0.5-30 nm.

3. The method of claim 2, wherein the TaNₓ layer is formed by reactive sputtering at 150-450° C. and has a thickness between about 0.5-5.0 nm and wherein the TaNₓ layer and the Ta layer are deposited in a same process chamber.

4. The method of claim 1, wherein the TaNₓ and Ta layers have a combined thickness that is at least 10% of a width of the opening.

5. The method of claim 1, wherein forming one or more conducting layers on the Ta layer comprises forming a Cu alloy layer and a Cu seed layer.

6. The method of claim 1, wherein the one or more conducting layers or the conducting material comprise Al, Cu, Ru, Ni, Co, Cr, Fe, Mn, Ti, Hf, Ta, W, V, Mo, Pd, Au, Ag, Pt, or combinations thereof.

7. A backend interconnect structure comprising:
a first via in a first dielectric layer, the first via having at least one surface;
a TaNₓ layer formed on the at least one surface of the first via, wherein x is approximately between about 0.05-2.0;
a Ta layer formed on the TaNₓ layer, wherein the Ta layer exhibits a body-centered cubic (BCC) structure;
one or more conducting layers formed on the Ta layer; and
a conducting material in the via.

8. The interconnect structure of claim 7, wherein the via has a first sidewall and a second sidewall opposite the first sidewall, the TaNₓ and Ta layers are on both the first sidewall and the second sidewall, and a combined thickness of the TaNₓ layer and Ta layer on the first sidewall and the TaNₓ layer and Ta layer on the second sidewall is at least 25% of a thickness of the conducting layers and the conducting material between the TaNₓ layer and Ta layer on the first sidewall and the TaNₓ layer and Ta layer on the second sidewall.

9. The interconnect structure of claim 8, wherein the TaNₓ layer is formed by reactive sputtering at a temperature between about 150-450° C. and has a thickness between about 0.5-5.0 nm.

10. The interconnect structure of claim 7, wherein the first via has a depth of about 100 nm or less and the Ta layer has a thickness between about 1-20 nm.

11. The interconnect structure of claim 7, wherein the one or more conducting layers on the Ta layer comprise a Cu alloy layer and a Cu seed layer.

12. The interconnect structure of claim 7, wherein the one or more conducting layers or the conducting material comprise Al, Cu, Ru, Ni, Co, Cr, Fe, Mn, Ti, Hf, Ta, W, V, Mo, Pd, Au, Ag, Pt, or combinations thereof.

13. The interconnect structure of claim 7 further comprising:
a second via in a second dielectric layer, the second dielectric layer being at least two layers of metallization above the first dielectric layer, the second via having at least one surface;
a TaNₓ layer formed on the at least one surface of the second via; and
a Ta layer formed on the TaNₓ layer, wherein the Ta layer has a tetragonal structure.

14. An integrated circuit (IC) chip comprising:
a substrate having a top surface;
one or more transistor structures with at least a portion of the transistor structures above the top surface of the substrate; and
a backend interconnect connecting the one or more transistor structures, wherein the backend interconnect comprises:
a first via in a first dielectric layer, the first via having at least one surface;
a TaNₓ layer formed on the at least one surface of the first via, wherein x is approximately between about 0.05-2.0;
a Ta layer formed on the TaNₓ layer; wherein the Ta layer exhibits a body-centered cubic (BCC) structure;
one or more conducting layers on the Ta layer; and
a conducting material in the via.

15. The IC chip of claim 14, wherein the via has a cross section with a bottom, a first sidewall and a second sidewall opposite the first sidewall the TaNₓ layer and Ta layers are both present on the bottom, first sidewall and second sidewall of the via, and the via has a width at a position above the TaNₓ layer and Ta layer that is on the bottom, wherein a combined thickness of the TaNₓ layer and Ta layer on the first sidewall and the TaNₓ layer and Ta layer on the second sidewall is at least 20% of the width of the via.

16. The IC chip of claim 14, wherein the Ta layer is formed by sputtering at a temperature between about 150-450° C. with a re-sputter rate between about 1.0-1.35 and has a thickness between about 0.5-30 nm and the TaNₓ layer is formed by reactive sputtering at a temperature between about 150-450° C. and has a thickness between about 0.5-5.0 nm.

17. The IC chip of claim 14, wherein the first via has a depth of about 100 nm or less and the Ta layer has a thickness between about 1-20 nm.

18. The IC chip of claim 14, wherein the one or more conducting layers on the Ta layer comprise a Cu alloy layer and a Cu seed layer.

19. The IC chip of claim 14, wherein the one or more conducting layers or the conducting material comprise Al, Cu, Ru, Ni, Co, Cr, Fe, Mn, Ti, Hf, Ta, W, V, Mo, Pd, Au, Ag, Pt, or combinations thereof.

20. The IC chip of claim 14 further comprising:
a second via in a second dielectric layer, the second via being farther from the substrate than the first via, the second via having at least one surface;
a TaNₓ layer formed on the at least one surface of the second via; and
a Ta layer formed on the TaNₓ layer, wherein the Ta layer has a tetragonal structure.

21. A computing device, comprising:
a board; and
a processor chip coupled to the board, the processor chip having a backend interconnect comprising a TaNₓ/Ta diffusion barrier layer, wherein the Ta has a body-centered cubic (BCC) structure.

22. The computing device of claim 21 further comprising a communication chip, a chipset, a memory, a data entry device, a display, a mass storage, or combinations thereof coupled to the board.
